(19) United States
(12) Patent Application Publication
(10) Pub. No.: US 2026/0367337 A1
(43) Pub. Date: Nov. 19, 2026

(54) OPTICAL FIBER TRANSMISSION METHOD AND DEVICE WITHOUT ALIGNMENT

(71) Applicant: SAULTECH TECHNOLOGY CO., LTD., Zhubei City (TW)

(72) Inventors: Yen-Hao Lu, Zhubei City (TW); Ching-Chuan Lien, Zhubei City (TW)

(73) Assignee: SAULTECH TECHNOLOGY CO., LTD., Zhubei City (TW)

(21) Appl. No.: 19/351,356

(22) Filed: Oct. 7, 2025

Related U.S. Application Data
(60) Provisional application No. 63/808,505, filed on May 19, 2025.

(51) Int. Cl. G02B 6/42; G02B 6/43; H10F 19/20; H10H 29/24; H10W 90/00

(52) U.S. Cl. CPC G02B 6/4202; G02B 6/4249; G02B 6/43; H10F 19/20; H10H 29/24; H10W 90/00

(57) ABSTRACT

An optical fiber transmission method without alignment is provided, including: a plurality of micro-LEDs are arranged on a first substrate to form a plurality of micro-LED assemblies, a plurality of micro-photodiodes are arranged on a second substrate to form a plurality of micro-photodiode assemblies, the first ends of a plurality of optical fibers are respectively aligned with the micro-LED assemblies, and the second ends of the optical fibers are respectively aligned with the micro-photodiode assemblies; the micro-LEDs in the micro-LED assemblies emit a plurality of optical signals; each optical fiber receives the optical signals emitted by the micro-LEDs in the aligned micro-LED assemblies; and each optical fiber transmits the optical signals to the micro-photodiodes in the aligned micro-photodiode assemblies.

### CROSS-REFERENCE TO RELATED APPLICATION

This application claims the priority of US application No. 63/808,505, filed on May 19, 2025, which is incorporated herewith by reference.

### BACKGROUND OF THE INVENTION

### 1. Field of the Invention

The present invention relates generally to a fiber optic transmission method and device, and more particularly, to a fiber optic transmission method and device that utilizes optical fibers to transmit optical signals between a micro-LED and a micro-photodiode without requiring alignment.

### 2. The Prior Arts

In graphics processors or other high-performance computing modules, optical interconnects using optical fibers for high-bandwidth inter-chip communication can provide low-latency, high-throughput data transmission capabilities.

A conventional optical fiber transmission method includes the following steps: disposing a plurality of micro light-emitting diodes (micro LEDs) on a first substrate, disposing a plurality of micro photodiodes (micro PDs) on a second substrate, aligning a first end of a plurality of optical fibers with the micro LEDs, aligning a second end of the optical fibers with the micro photodiodes, and disposing a plurality of lenses between the micro LEDs and the first ends of the optical fibers; the micro LEDs emitting a plurality of optical signals; the lenses focusing or collimating the optical signals; the optical fibers receiving the optical signals; the optical fibers transmitting the optical signals to the micro photodiodes; and the micro photodiodes receiving the optical signals and converting them into a plurality of electrical signals.

A conventional optical fiber transmission device includes a first substrate, a second substrate, a plurality of micro-LEDs, a plurality of micro-photodiodes, a plurality of optical fibers, and a plurality of lenses. The micro-LEDs are disposed on the first substrate, the micro-photodiodes are disposed on the second substrate, a first end of each optical fiber is aligned with each micro-LED, and a second end of each optical fiber is aligned with each micro-photodiode. The lenses are disposed between each micro-LED and the first end of each optical fiber.

However, as each optical fiber serves as a channel to transmit the optical signal from each micro-LED to each micro-photodiode, alignment must be very precise, and a lens must be disposed between each optical fiber and each micro-LED, increasing manufacturing costs.

### SUMMARY OF THE INVENTION

A primary objective of the present invention is to provide an optical fiber transmission method and device without alignment, in which each optical fiber serves as a channel to transmit optical signals from a plurality of micro-LEDs to a plurality of micro-photodiodes.

To achieve the aforementioned objective, the present invention provides an optical fiber transmission method without alignment, comprising the following steps: disposing a plurality of micro-LEDs a first substrate to form a plurality of micro-LED assemblies; disposing a plurality of micro-photodiodes on a second substrate to form a plurality of micro-photodiode assemblies; aligning a first end of a plurality of optical fibers with the micro-LED assemblies and aligning a second end of the optical fibers with the micro-photodiode assemblies; the micro-LEDs in the micro-LED assemblies emitting a plurality of optical signals; each optical fiber receiving the optical signals emitted by each corresponding micro-LED in the aligned micro-LED assemblies; and each optical fiber transmitting the optical signals to the corresponding micro-photodiode in the aligned micro-photodiode assemblies.

In a preferred embodiment, the distance between the first substrate and the second substrate is less than or equal to two meters.

In a preferred embodiment, the micro-LED assemblies are arranged in a regular pattern, and the micro-photodiode assemblies are arranged randomly.

In a preferred embodiment, the micro-LED assemblies are arranged in a regular pattern, and the micro-photodiode assemblies are arranged in a regular pattern.

In a preferred embodiment, the micro-LED assemblies are arranged randomly, and the micro-photodiode assemblies are arranged randomly.

To achieve the aforementioned objective, the present invention provides an optical fiber transmission device without alignment, comprising a first substrate, a second substrate, a plurality of micro-LEDs, a plurality of micro-photodiodes, and a plurality of optical fibers; the micro-LEDs are disposed on the first substrate and form a plurality of micro-LED assemblies and the micro-LEDs in the micro-LED assemblies emit a plurality of optical signals; the micro-photodiodes are disposed on the second substrate and form a plurality of micro-photodiode assemblies; the first ends of the optical fibers are aligned with the micro-LED assemblies, respectively, and the second ends of the optical fibers are aligned with the micro-photodiode assemblies, respectively, wherein each optical fiber receives the optical signal emitted by the corresponding micro-LED in the aligned micro-LED assemblies, and each optical fiber transmitting the optical signal to the corresponding micro-photodiodes in the aligned micro-photodiode assemblies.

In a preferred embodiment, the distance between the first substrate and the second substrate is less than or equal to two meters.

In a preferred embodiment, the micro-LED assemblies are arranged in a regular pattern, and the micro-photodiode assemblies are arranged randomly.

In a preferred embodiment, the micro-LED assemblies are arranged in a regular pattern, and the micro-photodiode assemblies are arranged in a regular pattern.

In a preferred embodiment, the micro-LED assemblies are arranged randomly, and the micro-photodiode assemblies are arranged randomly.

The present invention is effective in that each optical fiber serves as a channel to transmit optical signals from a plurality of micro-LEDs to a plurality of micro-photodiodes, eliminating the need for precise alignment and lenses, thereby reducing manufacturing costs.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a flow chart of a first embodiment of the fiber optic transmission method without alignment of the present invention.

FIG. 2 is a side view of the first embodiment of the fiber optic transmission device without alignment of the present invention.

FIG. 3 is a top view of the first embodiment of the fiber optic transmission device without alignment of the present invention.

FIG. 4 is a side view of a second embodiment of the fiber optic transmission device without alignment of the present invention.

FIG. 5 is a top view of the second embodiment of the fiber optic transmission device without alignment of the present invention.

FIG. 6 is a side view of a third embodiment of the fiber optic transmission device without alignment of the present invention.

FIG. 7 is a top view of the third embodiment of the fiber optic transmission device without alignment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

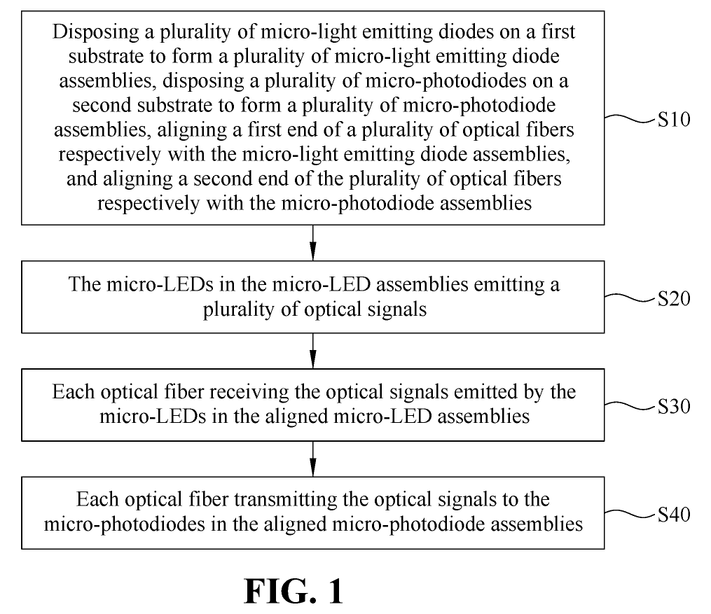

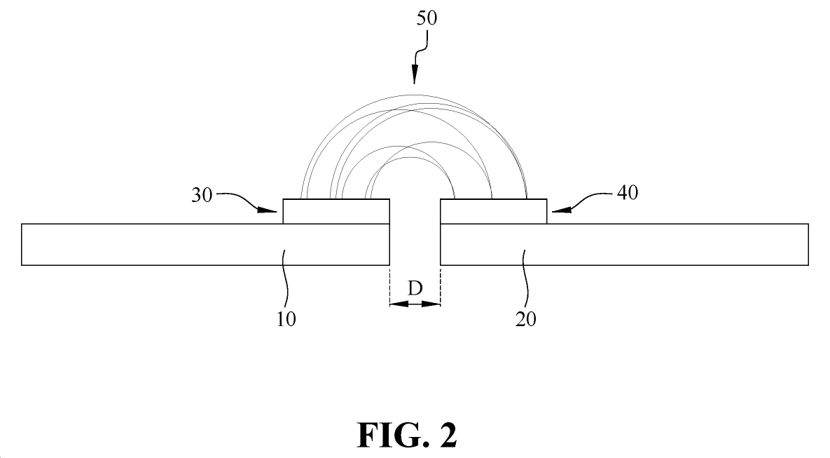

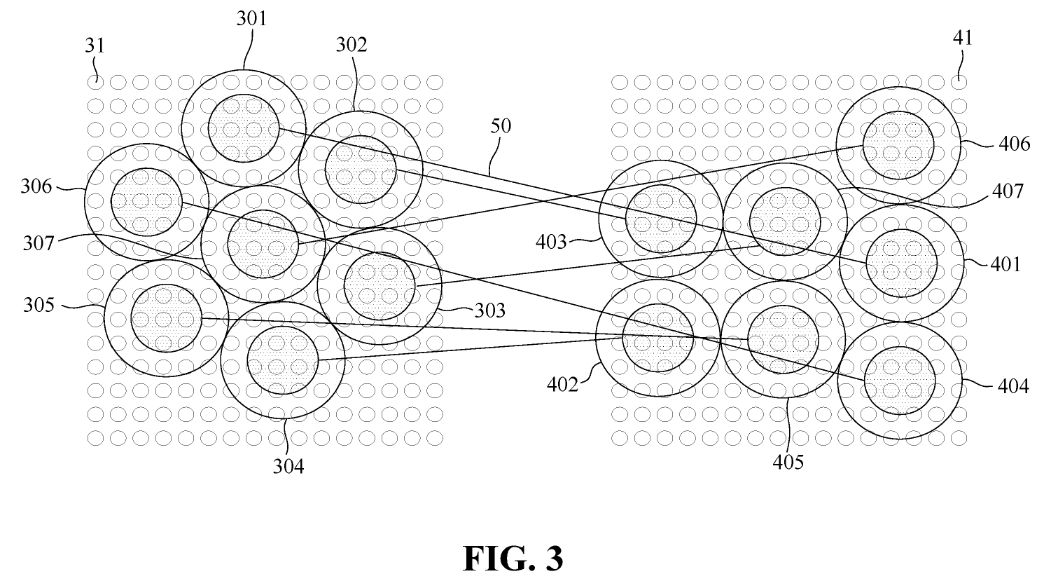

FIG. 1 is a flow chart of a first embodiment of an optical fiber transmission method without alignment of the present invention. FIG. 2 is a side view of a first embodiment of an optical fiber transmission device without alignment of the present invention. FIG. 3 is a top view of a first embodiment of an optical fiber transmission device without alignment of the present invention. As shown in FIGS. 1, 2 and 3, the present invention provides an optical fiber transmission method without alignment, comprising the following steps: Step S10, disposing a plurality of micro-light emitting diodes 31 on a first substrate 10 to form a plurality of micro-light emitting diode assemblies 30, disposing a plurality of micro-photodiodes 41 on a second substrate 20 to form a plurality of micro-photodiode assemblies 40, aligning a first end of a plurality of optical fibers 50 respectively with the micro-light emitting diode assemblies 30, and aligning a second end of the plurality of optical fibers 50 respectively with the micro-photodiode assemblies 40. In step S20, the micro-LEDs 31 in the micro-LED assemblies 30 emit a plurality of optical signals. In step S30, each optical fiber 50 receives the optical signals emitted by the micro-LEDs 31 in the aligned micro-LED assemblies 30. In step S40, each optical fiber 50 transmits the optical signals to the micro-photodiodes 41 in the aligned micro-photodiode assemblies 40.

As shown in FIGS. 2 and 3, the present invention provides an optical fiber transmission device without alignment, comprising a first substrate 10, a second substrate 20, a plurality of micro-LEDs 31, a plurality of micro-photodiodes 41 (micro-PDs), and a plurality of optical fibers 50. The micro-LEDs 31 are disposed on the first substrate 10 to form a plurality of micro-LED assemblies 30. The micro-LEDs 31 in the micro-LED assemblies 30 emit a plurality of optical signals. The micro-photodiodes 41 are disposed on the second substrate 20 to form a plurality of micro-photodiode assemblies 40. The first ends of the optical fibers 50 are aligned with the micro-LED assemblies 30, and the second ends of the optical fibers 50 are aligned with the micro-photodiode assemblies 40. Each optical fiber 50 receives the optical signals emitted by the micro-LEDs 31 in the aligned micro-LED assemblies 30 and transmits the optical signals to the micro-photodiodes 41 in the aligned micro-photodiode assemblies 40.

Thus, each optical fiber 50 serves as a channel to transmit the optical signals of the plurality of micro-LEDs 31 to the plurality of micro-photodiodes 41, eliminating the need for precise alignment and lenses, thereby reducing manufacturing costs.

Preferably, the distance D between the first substrate 10 and the second substrate 20 is less than or equal to two meters.

In the first embodiment, the micro-LED assemblies 30 are arranged in a regular pattern, and the micro-photodiode assemblies 40 are arranged randomly. For example, the micro-LED assemblies 30 include a first micro-LED assembly 301, a second micro-LED assembly 302, a third micro-LED assembly 303, a fourth micro-LED assembly 304, a fifth micro-LED assembly 305, a sixth micro-LED assembly 306, and a seventh micro-LED assembly 307. The seventh micro-LED assembly 307 is disposed at the center of the first substrate 10, and the first micro-LED assembly 301, the second micro-LED assembly 302, the third micro-LED assembly 303, the fourth micro-LED assembly 304, the fifth micro-LED assembly 305, and the sixth micro-LED assembly 306 are disposed around the seventh micro-LED assembly 307; the micro-photodiode assemblies 40 include a first micro-photodiode assembly 401, a second micro-photodiode assembly 402, a third micro-photodiode assembly 403, a fourth micro-photodiode assembly 404, a fifth micro-photodiode assembly 405, a sixth micro-photodiode assembly 406, and a seventh micro-photodiode assembly 407. The arrangement of the first micro-photodiode assembly 401, the second micro-photodiode assembly 402, the third micro-photodiode assembly 403, the fourth micro-photodiode assembly 404, the fifth micro-photodiode assembly 405, the sixth micro-photodiode assembly 406, and the seventh micro-photodiode assembly 407 is not regular.

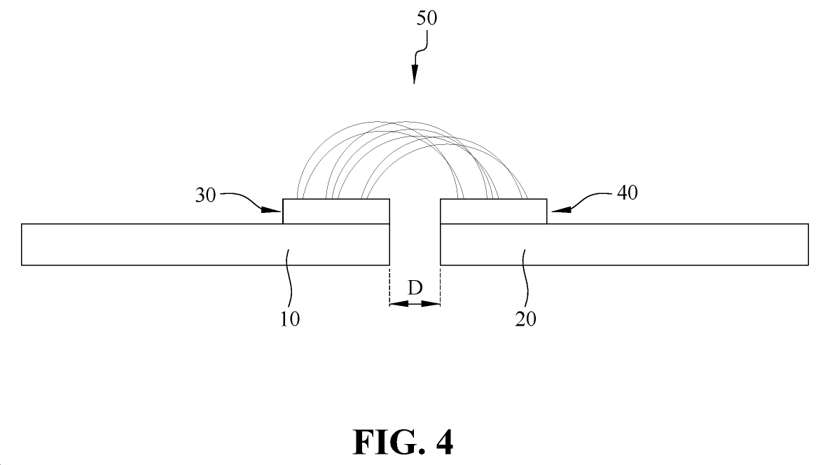

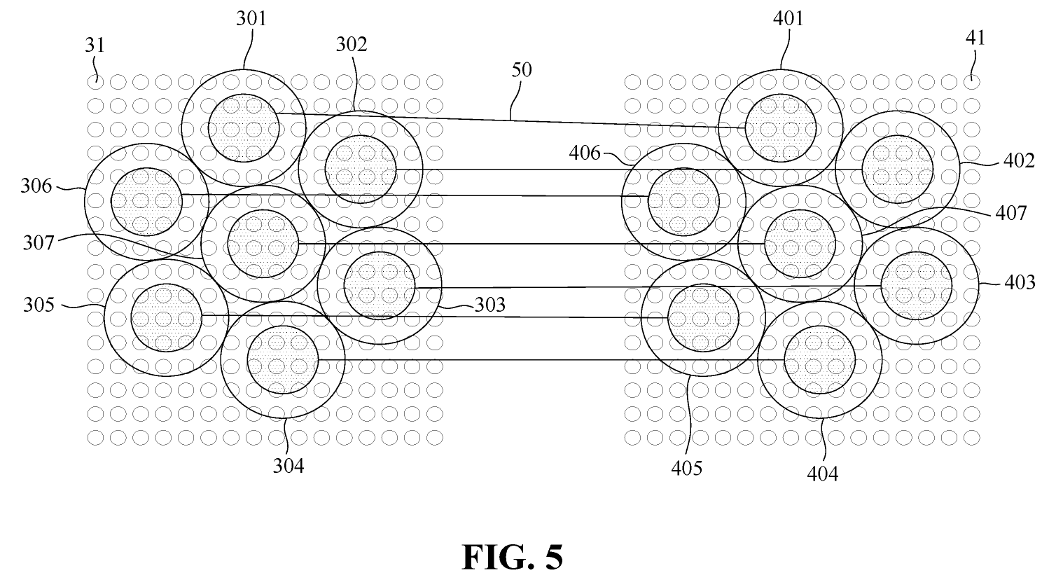

FIG. 4 is a side view of a second embodiment of the optical fiber transmission device without alignment of the present invention. FIG. 5 is a top view of the second embodiment of the optical fiber transmission device without alignment of the present invention. As shown in FIGS. 4 and 5, the structural difference between the second embodiment and the first embodiment lies in that the micro-photodiode assemblies 40 are arranged in a regular pattern. For example, the seventh micro-photodiode assembly 407 is disposed at the center of the second substrate 20, and the first micro-photodiode assembly 401, the second micro-photodiode assembly 402, the third micro-photodiode assembly 403, the fourth micro-photodiode assembly 404, the fifth micro-photodiode assembly 405, and the sixth micro-photodiode assembly 406 are disposed around the seventh micro-photodiode assembly 407.

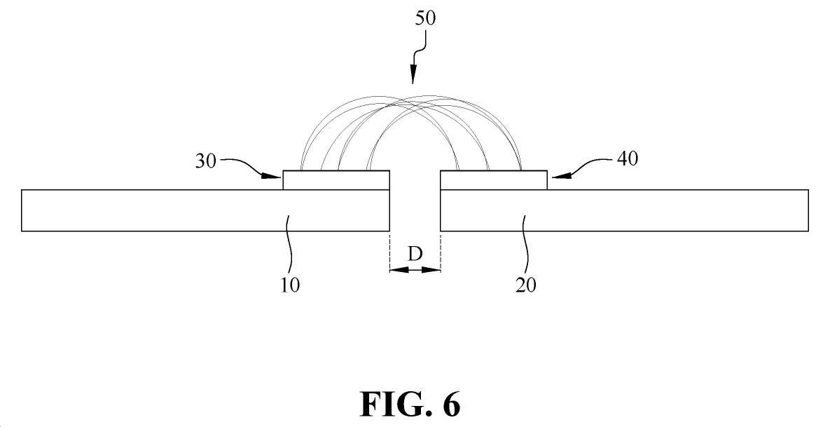

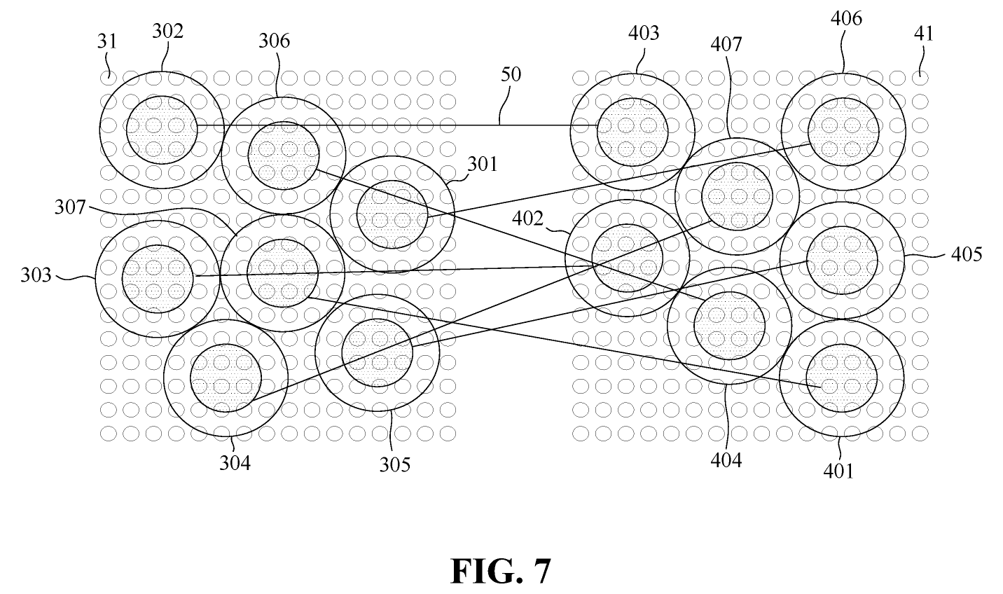

FIG. 6 is a side view of the third embodiment of the optical fiber transmission device without alignment of the present invention. FIG. 7 is a top view of the third embodiment of the optical fiber transmission device without alignment of the present invention. As shown in FIGS. 6 and 7, the structural difference between the third embodiment and the first embodiment is that the arrangement of the first micro-LED assembly 301, the second micro-LED assembly 302, the third micro-LED assembly 303, the fourth micro-LED assembly 304, the fifth micro-LED assembly 305, the sixth micro-LED assembly 306 and the seventh micro-LED assembly 307 is not regular.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. An optical fiber transmission method without alignment, comprising the steps of:
disposing a plurality of micro-LEDs a first substrate to form a plurality of micro-LED assemblies, disposing a plurality of micro-photodiodes on a second substrate to form a plurality of micro-photodiode assemblies, aligning a first end of a plurality of optical fibers with the micro-LED assemblies and aligning a second end of the optical fibers with the micro-photodiode assemblies;
the micro-LEDs in the micro-LED assemblies emitting a plurality of optical signals;
each optical fiber receiving the optical signals emitted by each corresponding micro-LED in the aligned micro-LED assemblies; and
each optical fiber transmitting the optical signals to the corresponding micro-photodiode in the aligned micro-photodiode assemblies.

2. The optical fiber transmission method without alignment according to claim 1, wherein the distance between the first substrate and the second substrate is less than or equal to two meters.

3. The optical fiber transmission method without alignment according to claim 1, wherein the micro-LED assemblies are arranged in a regular pattern, and the micro-photodiode assemblies are arranged randomly.

4. The optical fiber transmission method without alignment according to claim 1, wherein the micro-LED assemblies are arranged in a regular pattern, and the micro-photodiode assemblies are arranged in a regular pattern.

5. The optical fiber transmission method without alignment according to claim 1, wherein the micro-LED assemblies are arranged randomly, and the micro-photodiode assemblies are arranged randomly.

6. An optical fiber transmission device without alignment, comprising:
a first substrate;
a second substrate;
a plurality of micro-LEDs, disposed on the first substrate to form a plurality of micro-LED assemblies, and the micro-LEDs in the micro-LED assemblies emitting a plurality of optical signals;
a plurality of micro-photodiodes, disposed on the second substrate to form a plurality of micro-photodiode assemblies; and
a plurality of optical fibers, with the first ends of the optical fibers aligned respectively with the micro-LED assemblies, and the second ends of the optical fibers respectively aligned with the micro-photodiode assemblies;
wherein each optical fiber receiving the optical signal emitted by the corresponding micro-LED in the aligned micro-LED assemblies, and each optical fiber transmitting the optical signal to the corresponding micro-photodiodes in the aligned micro-photodiode assemblies.

7. The optical fiber transmission device without alignment according to claim 6, wherein the distance between the first substrate and the second substrate is less than or equal to two meters.

8. The optical fiber transmission device without alignment according to claim 6, wherein the micro-LED assemblies are arranged in a regular pattern, and the micro-photodiode assemblies are arranged randomly.

9. The optical fiber transmission device without alignment according to claim 6, wherein the micro-LED assemblies are arranged in a regular pattern, and the micro-photodiode assemblies are arranged in a regular pattern.

10. The optical fiber transmission device without alignment according to claim 6, wherein the micro-LED assemblies are arranged randomly, and the micro-photodiode assemblies are arranged randomly.
